(19) United States
(12) Patent Application Publication
(10) Pub. No.: US 2015/0200664 A1
(43) Pub. Date: Jul. 16, 2015

(54) TOUCH SENSOR

(71) Applicant: SAMSUNG ELECTRO-MECHANICS CO., LTD., Gyeonggi-Do (KR)

(72) Inventors: Jae Hun KIM, Gyeonggi-Do (KR); Jin Uk LEE, Gyeonggi-Do (KR)

(73) Assignee: SAMSUNG ELECTRO-MECHANICS CO., LTD., Gyeonggi-Do (KR)

(21) Appl. No.: 14/304,207

(22) Filed: Jun. 13, 2014

(30) Foreign Application Priority Data
Jan. 10, 2014 (KR) 10-2014-0003445

(51) Int. Cl. H03K 17/96

(52) U.S. Cl. CPC H03K 17/9618; H03K 2017/9615; H03K 2217/96015

(57) ABSTRACT

Embodiments of the invention provide a touch sensor and a method of manufacturing the touch sensor. The touch sensor includes a base substrate, and an electrode pattern formed on the base substrate. The electrode pattern includes a first pattern layer formed on the base substrate, a second pattern layer formed on the first pattern layer, and a third pattern layer formed to enclose the second pattern layer. The third pattern layer is formed to cover a side and an exposed upper surface of the second pattern layer and is made of tin.

### CROSS REFERENCE TO RELATED APPLICATION

This application claims the benefit of and priority under 35 U.S.C. §119 to Korean Patent Application No. KR 10-2014-0003445, entitled “TOUCH SENSOR,” filed on Jan. 10, 2014, which is hereby incorporated by reference in its entirety into this application.

### BACKGROUND

1. Field of the Invention

The present invention relates to a touch sensor.

2. Description of the Related Art

With the development of computers using a digital technology, computer-aided devices have been developed, and personal computers, portable transmitters and other personal information processors execute processing of texts and graphics using a variety of input devices, such as a keyboard and a mouse.

With the rapid advancement of an information-oriented society, the use of computers has gradually been expanded; however, it is difficult to efficiently operate these products using only a keyboard and a mouse as input devices. Therefore, the necessity for a device, which has a simple configuration and lower occurrences of malfunction and is configured for anyone to easily input information, has increased.

In addition, current techniques for input devices have progressed toward techniques related to high reliability, durability, innovation, designing and processing beyond the level of satisfying general functions. To this end, a touch sensor has been developed as an input device capable of inputting information, such as text and graphics.

The conventional touch sensor is mounted on a display surface of a display, such as an electronic organizer, a flat panel display device, including a liquid crystal display (LCD) device, a plasma display panel (PDP), an electroluminescence (El) element, as non-limiting examples, or a cathode ray tube (CRT) to allow a user to select desired information while viewing the display.

Further, the conventional touch sensor is classified into a resistive-type touch sensor, a capacitive-type touch sensor, an electro-magnetic-type touch sensor, a surface acoustic wave (SAW)-type touch sensor, and an infrared-type touch sensor. These various types of touch sensors are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive-type touch sensor and the capacitive-type touch sensor have been prominently used in a wide range of fields.

Meanwhile, an electrode of the touch sensor in a touch screen panel (TSP) field uses indium thin oxide (ITO), which is being currently widely used as a transparent electrode. However, the transparent electrode using the indium thin oxide is expensive and has a limited supply and a high resistance, and therefore it is difficult to implement a large touch sensor. Therefore, research has been conducted to develop replacements for the transparent electrode, and therefore various types of new touch sensors have been proposed.

For example, a metal mesh having a low resistance, which is suitable for the touch sensor, has been developed. However, the metal mesh has an opaque pattern, and therefore suffers from degraded visibility and is sensitive to moisture, and therefore is easily oxidized. Further, it has been known that a method of forming an electrode using the metal mesh comes closest to commercialization. However, to replace the existing transparent electrode, it is required to ensure the same or higher reliability.

Korean Patent Publication No. KR 10-2013-0005093 has proposed a technology of forming a sensing electrode in a net shape using a metal thin film by replacing the existing ITO in the touch panel. By doing so, it is possible to improve detection sensitivity and permeability by reducing resistance between the sensing electrodes or between the sensing electrode and the wiring electrode.

However, when the sensing electrode is formed of the metal thin film, there is a problem in that the sensing electrode may be visualized by a user. In particular, it is difficult to implement a fine pattern during the patterning process for forming the sensing electrode, the sensing electrode may not be easily visualized due to the opacity of the metal electrode used for conductivity, and the reliability of the exposed sensing electrode, may be degraded due to corrosion.

### SUMMARY

Accordingly, embodiments of the invention have been made in an effort to provide a technology of improving characteristics of corrosion resistance and visibility of an electrode pattern by forming the electrode pattern in a structure including a first pattern layer, a second pattern layer, and a third pattern layer in a touch sensor to which a metal electrode is applied.

Furthermore, embodiments of the invention have been made in an effort to provide a technology of forming a first pattern layer using a nickel alloy to improve an adhesion between a base substrate and an electrode pattern.

Furthermore, embodiments of the invention have been made in an effort to provide a technology of forming a third pattern layer on a side of a second pattern layer and an exposed upper surface thereof by using tin displacement plating.

Furthermore, embodiments of the invention have been made in an effort to provide a technology of forming a third pattern layer of an electrode pattern to cover a side and an exposed upper surface of a second pattern layer to prevent a metal forming the second pattern layer from being visualized by user's eyes.

Furthermore, embodiments of the invention have been made in an effort to provide a technology of forming a third pattern layer of an electrode pattern to prevent a second pattern layer vulnerable to high temperature and high humidity environment conditions from corroding.

According to an embodiment of the invention, there is provided a touch sensor, including a base substrate, and an electrode pattern formed on the base substrate. The electrode pattern includes a first pattern layer formed on the base substrate, a second pattern layer formed on the first pattern layer, and a third pattern layer formed to enclose the second pattern layer. The third pattern layer is formed to cover a side and an exposed upper surface of the second pattern layer and is made of tin.

According to an embodiment, the first pattern layer and the third pattern layer are made of different materials.

According to an embodiment, the first pattern layer is made of a nickel alloy and the nickel alloy may be made of nickel-chromium (Ni—Cr), nickel-copper (Ni—Cu), nickel-titanium (Ni—Ti), or a combination thereof.

According to an embodiment, the second pattern layer is made of copper (Cu), aluminum (Al), gold (Au), silver (Ag), titanium (Ti), palladium Pd), chromium (Cr), nickel or a combination thereof.

According to an embodiment, the electrode pattern is formed in a mesh pattern.

According to another embodiment of the invention, there is provided a method of manufacturing a touch sensor, including preparing a base substrate, forming a first plating layer on the base substrate, forming a second plating layer on the first plating layer, forming a patterned etching resist for forming an electrode pattern on the second plating layer, forming a first pattern layer and a second pattern layer by etching the first plating layer and the second plating layer; and treating an exposed outer surface including a side of the second pattern layer with tin displacement plating.

According to an embodiment, the first pattern layer and the third pattern layer are made of different materials.

According to an embodiment, the first pattern layer is made of a nickel alloy and the nickel alloy may be made of nickel-chromium (Ni—Cr), nickel-copper (Ni—Cu), nickel-titanium (Ni—Ti), or a combination thereof.

According to an embodiment, the second pattern layer is made of copper (Cu), aluminum (Al), gold (Au), silver (Ag), titanium (Ti), palladium (Pd), chromium (Cr), nickel (Ni), or a combination thereof.

According to an embodiment, the method of manufacturing a touch sensor further includes, after the treating the exposed outer surface, additionally etching an edge portion of the first pattern layer.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a cross-sectional view of a touch sensor electrode pattern according to an embodiment of the invention.

FIGS. 2 to 7 are cross-sectional views of a manufacturing process flow for describing a method of manufacturing an electrode pattern of a touch senor according to an embodiment of the invention.

FIG. 8 is a cross-sectional view of a manufacturing process flow for describing a method of manufacturing an electrode pattern of a touch senor according to another embodiment of the invention.

### DETAILED DESCRIPTION

Advantages and features of the present invention and methods of accomplishing the same will be apparent by referring to embodiments described below in detail in connection with the accompanying drawings. However, the present invention is not ii fluted to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve, understanding of embodiments of the present invention, Like reference numerals refer to like elements throughout the specification.

Touch Sensor

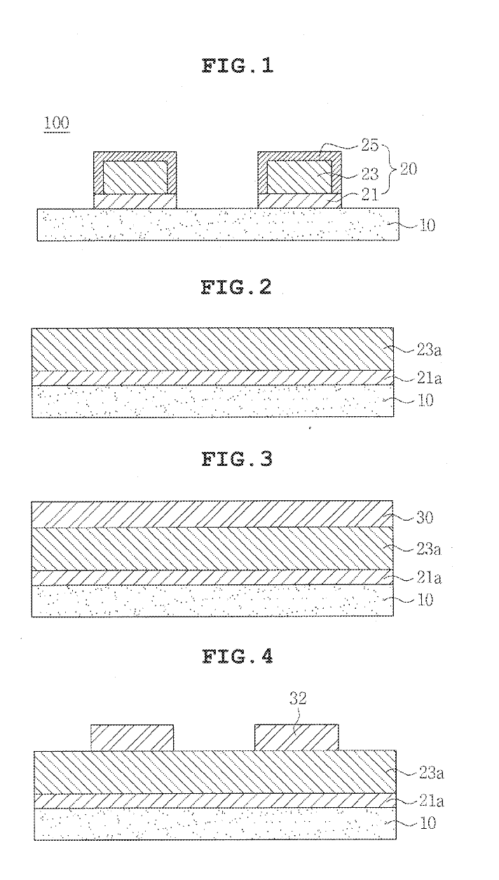

FIG. 1 is a cross-sectional view of a touch sensor electrode pattern according to an embodiment of the invention.

Referring to FIG. 1, a touch sensor 100, according to an embodiment of the invention, includes a base substrate 10 and an electrode pattern 20 formed on the base substrate 10, in which the electrode pattern 20 includes a first pattern layer 21 formed on the base substrate 10, a second pattern layer 23 formed on the first pattern layer 21, and a third pattern layer 25 formed to enclose the second pattern layer 23. According to at least one embodiment, the third pattern layer 25 is formed to cover a side and an exposed upper surface of the second pattern layer 23 and may be made of tin Sn.

As a material of the base member 10, at least one of polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass, or tempered glass, as non-limiting examples, is used. Further, the base substrate is easily selected and applied from transparent materials by those skilled in the art in addition to the foregoing materials.

According to an embodiment, the electrode pattern 20 is formed on one surface or the other surface of the base substrate 10. The electrode pattern 20 includes a first pattern layer 21, a second pattern layer 23, and a third pattern 25, and is made of different materials.

According to an embodiment, in forming the electrode pattern 20 on the base substrate 10, the reason for dividing the electrode pattern 20 into a total of three layers of the first pattern layer 21, the second pattern layer 23, and the third pattern layer 25 is as follows:

In forming the electrode pattern 20 on the base substrate 10, the first pattern layer 21 is formed to improve an adhesion between the base substrate 10 and the electrode pattern 20.

According to an embodiment, the first pattern layer 21 is made of a nickel alloy. For example, the nickel alloy is made of nickel-chromium (Ni—Cr), nickel-copper (Ni—Cu), nickel-titanium (Ni—Ti), or a combination thereof.

Generally, there is a case in which a material forming the second pattern layer 23 is directly formed on the base substrate 10 to be used as the electrode pattern 20, but since the adhesion between the base substrate 10 and the material forming the second pattern layer 23 is weak, the touch sensor 100 may have a defect. However, the nickel alloy forming the first pattern layer 21, according to at least one embodiment of the invention, has a relatively more excellent adhesion with the base substrate 10 than an adhesion with a material forming the second pattern layer 23 and may form a thin film layer.

Therefore, the first pattern layer 21, which is made of a material different from a construction material of the second pattern layer 23 and has excellent adhesion with the base substrate 10 is first formed on the base substrate 10 to improve the adhesion between the base substrate 10 and the electrode pattern 20.

According to one embodiment, the second pattern layer 23 is formed to improve the operation performance and driving reliability of the touch sensor and may be formed on the first pattern layer 21.

According to one embodiment, the second pattern layer 23 is made of copper (Cu), aluminum (Al), gold (Au), silver (Ag), titanium (Ti), palladium (Pd), chromium (Cr), nickel (Ni), or a combination thereof.

According to one embodiment, the third pattern layer 25 is formed to prevent the metal forming the second pattern layer 23 from being visualized by user's eyes. The third pattern layer 25 is formed to enclose a side and an upper surface of the second pattern layer 23 and may be made of tin (Sn).

According to one embodiment, the third pattern layer 25 is also formed by stacking one layer made of tin (Sn) on the second pattern layer 23 and is formed by tin displacement of the second pattern layer, but is not limited thereto.

Features of a process by the tin displacement, according to at least one embodiment, will be described below.

The electrode pattern 20 of the touch sensor 100, according to an embodiment of the invention, improves the adhesion between the base substrate 10 and the electrode pattern 20 through the first pattern layer 21. The third pattern layer 25 is formed on the side and the upper surface exposed outside the second pattern layer 23 by using the tin displacement plating to prevent the second pattern layer 23 vulnerable to high temperature and high humidity environment conditions from corroding. Further, the third pattern layer 25, according to an embodiment of the invention, prevents the second pattern layer 23 from being visualized by the user's eyes.

According to one embodiment, the electrode pattern 20 is formed in a mesh pattern in which metal wires intersect each other, in which the mesh pattern has polygonal shapes, such as a quadrangular shape, a triangular shape, and a diamond shape, but is not particularly limited thereto.

Although not illustrated, in the touch sensor 100, according to an embodiment of the invention, a window substrate for protecting the electrode pattern 20 is formed on the electrode pattern 20 which is formed on one surface of the base substrate 10.

Further, according to one embodiment, the other surface of the base substrate 10 is also provided with a display for displaying an output value input through the touch sensor 100 by the user.

According to one embodiment, the window substrate is made of tempered glass, as non-limiting examples, and is formed, for example, by coating a material, which may be protected from the outside.

According to one embodiment, the display includes various display devices, such as a LCD or an OLED, as an image device.

Method of Manufacturing Touch Sensor

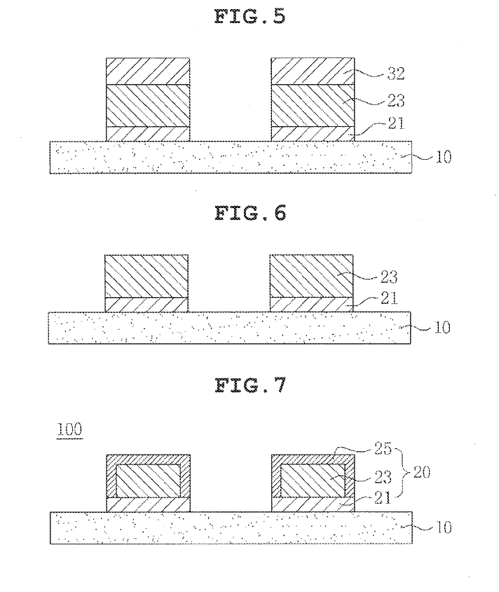

FIGS. 2 to 7 are cross-sectional views of a manufacturing process flow for describing a method of manufacturing an electrode pattern of a touch senor according to an embodiment of the invention.

A method of manufacturing a touch sensor 100, according to an embodiment of the invention, includes (A) preparing the base substrate 10, (B) forming a first plating layer 21a on the base substrate 10, (C) forming a second plating layer 23a on the first plating layer 21a, (D) forming a patterned etching resist 32 for forming the electrode pattern 20 on the second plating layer 23a, (E) forming the first pattern layer 21 and the second pattern layer 23 by etching the first plating layer 21a and the second plating layer 23a, and (F) treating an exposed outer surface including the side of the second pattern layer 23 with the tin displacement plating.

According to one embodiment, the process of forming the first plating layer 21a and the second plating layer 23a on the base substrate 10 may be illustrated in FIG. 2.

According to one embodiment, the method of forming the first plating layer 21a and the second plating layer 23a on the base substrate 10 is not particularly limited, but is formed, for example, by a dry process, a wet process, or a direct patterning process. Here, the dry process includes, for example, sputtering and evaporation, the wet process includes, for example, dip coating, spin coating, roll coating, and spray coating, and the direct patterning process means, for example, screen printing, gravure printing, and inkjet printing.

Referring to FIGS. 3 to 6, the etching resist layer 30 is formed on the second plating layer 23a to form the electrode pattern 20 and the etching resist pattern 32 is formed by an exposure and etching process.

According to an embodiment, a method of forming the etching resist pattern 32 is performed by exposing the etching resist layer 30 of a region, which does not correspond to the electrode pattern 20 and then removing the exposed region with a developer.

According to one embodiment, the process of removing the first plating layer 21a and the second plating layer 23a, which are exposed in a region from which the exposed etching resist layer 30 is removed, is removed with an etchant which may be generally used in the art.

By doing so, the electrode pattern 20 including the first pattern layer 21 and the second pattern layer 23 is formed on the base substrate 10 and the etching resist pattern 32 remaining on the electrode pattern 20 is removed with a stripper which may be generally used in the art.

According to one embodiment, the electrode pattern 20 is formed on one surface or the other surface of the base substrate 10. The electrode pattern 20 includes a first pattern layer 21, a second pattern layer 23, and a third pattern layer 25, and is made of different materials.

According to one embodiment, the first pattern layer 21 is made of a nickel alloy. The nickel alloy is made of nickel-chromium (Ni—Cr), nickel-copper (Ni—Cu), nickel-titanium (Ni—Ti), or a combination thereof.

Further, the second pattern layer 23 is made of copper (Cu), aluminum (Al), gold (Au), silver (Ag), titanium (Ti), palladium (Pd), chromium (Cr), nickel (Ni), or a combination thereof.

Referring to FIG. 7, the method of manufacturing a touch sensor 100, according to an embodiment of the invention, includes treating the exposed outer surface including the side and the upper surface of the second pattern layer 23 of the electrode pattern 20 with the tin displacement plating to form the third pattern layer 25.

According to one embodiment, the third pattern layer 25 is formed to enclose a side and an upper surface of the second pattern layer 23 and is made of tin (Sn). The third pattern layer 25 is not formed by stacking one layer on the second pattern layer 23, but may be formed by the tin displacement plating.

Herein, the tin displacement plating is called electroless tin plating and means, for example, performing tin plating using displacement reaction. For example, to form the third pattern layer 25 on the second pattern layer 23 including copper (Cu), a tin displacement bath, which includes stannous chloride, thiourea, hydrochloric acid (HCl), hypophosphorous acid sodium (Na₂H₂PO₂ H₂O), and a surfactant is used.

In the tin displacement bath, according to an embodiment of the invention, the thiourea complexes copper ions to make the tin ions is substituted and educed on copper and has an excellent adhesion. Further, the tin displacement bath is also further added with sodium hyphophosphite (Na₂H₂PO₂) as an antioxidant of tin ion. A process of forming the third pattern layer 25 on the second pattern layer 23 including copper by the tin displacement plating may be appreciated from the following Reaction Formula I.

Sn²⁺+2Cu→Sn+2Cu⁺ [Reaction Formula 1]

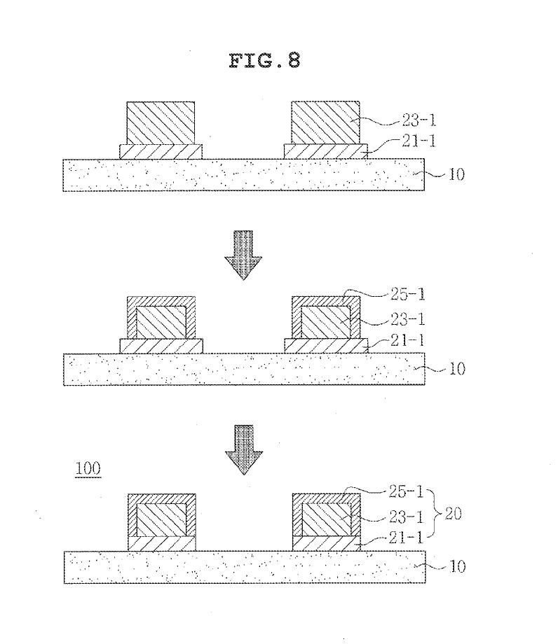

FIG. 8 is a cross-sectional view of a manufacturing process flow for describing a method of manufacturing an electrode pattern of a touch senor according to another embodiment of the invention.

Referring to FIG. 8, the touch sensor 100, according to another embodiment of the invention, leads to a difference in an etching rate between metal materials forming the first plating layer 21a and the second plating layer 23a during the etching process to form the first plating layer 21a and the second plating layer 23a formed on the base substrate 10 as the electrode pattern 20. The first plating layer 21a has a lower etching rate than that of the second plating layer 23a, such that a step between the etched first pattern layer 21 and second pattern layer 23 occurs.

In the touch sensor 100, according to another embodiment of the invention, the first plating layer 21a and the second plating layer 23a formed on the base substrate are formed and the first pattern layer 21, the second pattern layer 23, and the third pattern layer 25 are formed by the etching process to form the electrode pattern 20. However, the construction material between the respective layers is different and therefore the difference in the etching rate occurs, such that the step occurs.

Therefore, to prevent the step from occurring, a process of etching an edge portion of the first pattern layer 21 of the electrode pattern 20 is additionally included.

According to the touch sensor, according to various embodiments of the invention, it is possible to improve the characteristics of the corrosion resistance and the visibility of the electrode pattern by forming the electrode pattern in the structure including the first pattern layer, the second pattern layer, and the third pattern layer.

Further, it is possible to improve the adhesion between the base substrate and the electrode pattern by forming the first pattern layer of the electrode pattern.

Further, it is possible to prevent the second pattern layer vulnerable to the high temperature and high humidity environment conditions by forming the third pattern layer of the electrode pattern from corroding.

Further, it s possible to prevent the opaque second pattern layer from being visualized by the user's eyes by forming the third pattern layer of the electrode pattern to cover the side and the upper surface of the second pattern layer.

Further, it is possible to improve the characteristics of the second pattern layer vulnerable to the reliability by forming the third pattern layer on the surface exposed outside the second pattern layer of the electrode pattern using the tin displacement plating.

Terms used herein are provided to explain embodiments, not limiting the present invention. Throughout this specification, the singular form includes the plural form unless the context clearly indicates otherwise., When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A touch sensor, comprising:
a base substrate; and
an electrode pattern formed on the base substrate,
wherein the electrode pattern comprises:
a first pattern layer formed on the base substrate,
a second pattern layer formed on the first pattern layer, and
a third pattern layer formed to enclose the second pattern layer, the third pattern layer being formed to cover a side and an exposed upper surface of the second pattern layer and is made of tin.

2. The touch sensor as set forth in claim 1, wherein the first pattern layer and the third pattern layer are made of different materials.

3. The touch sensor as set forth in claim 1, wherein the first pattern layer is made of a nickel alloy and the nickel alloy is made of nickel-chromium (Ni—Cr), nickel-copper (Ni—Cu), nickel-titanium (Ni—Ti), or a combination thereof.

4. The touch sensor as set forth in claim 1, wherein the second pattern layer is made of copper (Cu), aluminum (Al), gold (Au), silver (Ag), titanium (Ti), palladium (Pd), chromium (Cr), nickel (Ni), or a combination thereof.

5. The touch sensor as set forth in claim 1, wherein the electrode pattern is formed in a mesh pattern.

6. A method of manufacturing a touch sensor, comprising:
preparing a base substrate;
forming a first plating layer on the base substrate;
forming a second plating layer on the first plating layer;
forming a patterned etching resist for forming an electrode pattern on the second plating layer;
forming a first pattern layer and a second pattern layer by etching the first plating layer and the second plating layer; and
treating an exposed outer surface including a side of the second pattern layer with tin displacement plating.

7. The method as set forth in claim 6, wherein the first pattern layer and the third pattern layer are made of different materials.

8. The method as set forth in claim 6, wherein the first pattern Layer is made of a nickel alloy and the nickel alloy is made of nickel-chromium (Ni—Cr), nickel-copper (Ni—Cu), nickel-titanium (Ni—Ti), or a combination thereof.

9. The method as set forth in claim 6, wherein the second pattern layer is made of copper (Cu), aluminum (Al), gold (Au), silver (Ag), titanium (Ti), palladium (Pd), chromium (Cr), nickel (Ni), or a combination thereof.

10. The method as set forth in claim 6, further comprising:
after the treating the exposed outer surface, additionally etching an edge portion of the first pattern layer.
